(19) United States
(12) Patent Application Publication
(10) Pub. No.: US 2026/0190580 A1
(43) Pub. Date: Jul. 2, 2026

(54) DISPLAY MODULE AND DISPLAY DEVICE

(71) Applicants: Shouzheng WU, Shanghai (CN); Yuhui LAI, Shanghai (CN); Zhenyu JIA, Shanghai (CN); Yongxin HE, Shanghai (CN)

(72) Inventors: Shouzheng WU, Shanghai (CN); Yuhui LAI, Shanghai (CN); Zhenyu JIA, Shanghai (CN); Yongxin HE, Shanghai (CN)

(21) Appl. No.: 19/430,682

(22) Filed: Dec. 23, 2025

(30) Foreign Application Priority Data
Jul. 10, 2025 (CN) 202510956071.7

(51) Int. Cl. H10H 29/49; H10H 20/819; H10H 29/45

(52) U.S. Cl. CPC H10H 29/49; H10H 20/819; H10H 29/45

(57) ABSTRACT

Provided are a display module and a display device, including a first substrate and a second substrate, first and second signal lines, and a lap joint. A light-emitting surface of the display module is located on a side of the first substrate away from the second substrate. The first signal line extends from a side of the first substrate away from the second substrate, via a side surface of the first substrate, to a side of the first substrate close to the second substrate. The second signal line extends from a side of the second substrate close to the first substrate, via a side surface of the second substrate, to a side of the second substrate away from the first substrate. The lap joint is located between the first substrate and the second substrate. The first and second signal lines are electrically connected through the lap joint.

### CROSS-REFERENCE TO RELATED APPLICATIONS

The present application claims priority to Chinese Patent Application No. 202510956071.7, filed on Jul. 10, 2025, the content of which is incorporated herein by reference in its entirety.

### TECHNICAL FIELD

The present disclosure relates to the field of display technologies, and in particular, to a display module and a display device.

### BACKGROUND

Light-emitting diodes (LEDs) have advantages such as high brightness, high contrast, wide color gamut, large viewing-angle, low power consumption, and long service life, and have been widely used in the fields of display and lighting. Micro light-emitting diodes (micro-LEDs) or mini light-emitting diodes (mini-LEDs) are often used in spliced display products. Currently, spliced products have problems of low strength and poor impact resistance.

### SUMMARY

Embodiments of the present disclosure provide a display module and a display device, aiming to solve a technical problem in terms of improving the impact resistance of a display product.

In a first aspect, an embodiment of the present disclosure provides a display module. The display module includes a first substrate and a second substrate disposed opposite to each other, a first signal line and a second signal line, and a lap joint. A light-emitting surface of the display module is located on a side of the first substrate away from the second substrate. The first signal line extends from a side of the first substrate away from the second substrate, via a side surface of the first substrate, to a side of the first substrate close to the second substrate. The second signal line extends from a side of the second substrate close to the first substrate, via a side surface of the second substrate, to a side of the second substrate away from the first substrate. The lap joint is located between the first substrate and the second substrate. The first signal line and the second signal line are electrically connected through the lap joint.

In a second aspect, based on a same inventive concept, an embodiment of the present disclosure further provides a display device, including the display module provided by any embodiment of the present disclosure.

The display module and the display device provided by the embodiments of the present disclosure have the following beneficial effects. The two substrates provided in the display module can increase the overall structural strength, thereby improving the impact resistance of the display module. In addition, the first signal line and the second signal line respectively provided on the side surfaces of the two substrates are electrically connected through the lap joint located between the two substrates. That is, the side traces do not extend directly and continuously on the two sides of the first substrate and the second substrate. Therefore, the extending length of the side traces on a side of the substrates can be reduced, avoiding the impact of excessively long side traces on manufacturing yield. Additionally, an arrangement of the first signal line and the second signal line introduces display signals from a side of the second substrate away from the first substrate without performing a bonding process on a side of the first substrate, which can avoid damage to the film layer structure on the side of the first substrate by the process, thus improving the yield. The design of the embodiments of the present disclosure is conducive to increasing product yield and reducing costs.

### BRIEF DESCRIPTION OF DRAWINGS

In order to better illustrate the technical solutions in the embodiments of the present disclosure or the related art, the drawings used in the description of the embodiments will be briefly illustrated as follows. It should be noted that, the drawings described below are merely some of, rather than all of the embodiments of the present disclosure. Based on these drawings, those skilled in the art can obtain other drawings without any creative efforts.

FIG. 1 is a schematic diagram of a display module according to an embodiment of the present disclosure;

FIG. 2 is a schematic diagram of another display module according to an embodiment of the present disclosure;

FIG. 3 is a schematic diagram of another display module according to an embodiment of the present disclosure;

FIG. 4 is a schematic diagram of another display module according to an embodiment of the present disclosure;

FIG. 5 is a schematic diagram of another display module according to an embodiment of the present disclosure;

FIG. 6 is a schematic diagram of another display module according to an embodiment of the present disclosure;

FIG. 7A is a schematic diagram of another display module according to an embodiment of the present disclosure;

FIG. 7B is a schematic diagram of another display module according to an embodiment of the present disclosure;

FIG. 8 is a schematic diagram of another display module according to an embodiment of the present disclosure;

FIG. 9 is a schematic diagram of another display module according to an embodiment of the present disclosure;

FIG. 10 is a schematic diagram of another display module according to an embodiment of the present disclosure;

FIG. 11 is a schematic diagram of another display module according to an embodiment of the present disclosure;

FIG. 12 is a schematic diagram of another display module according to an embodiment of the present disclosure;

FIG. 13 is a schematic diagram of another display module according to an embodiment of the present disclosure;

FIG. 14 is a schematic diagram of another display module according to an embodiment of the present disclosure;

FIG. 15 is a schematic diagram of another display module according to an embodiment of the present disclosure; and

FIG. 16 is a schematic diagram of a display device according to an embodiment of the present disclosure.

### DESCRIPTION OF EMBODIMENTS

In order to better illustrate objectives, technical solutions, and advantages of embodiments of the present disclosure, the technical solutions in embodiments of the present disclosure are described in detail with reference to the drawings. It should be noted that, the embodiments described are only some rather than all of the embodiments of the present disclosure. All other embodiments obtained by those skilled in the art based on the embodiments of the present disclosure without creative efforts should fall within the protection scope of the present disclosure.

Terms used in the embodiments of the present disclosure are merely for the purpose of describing specific embodiments, but not intended to limit the present disclosure. The terms “a/an”, and “the/said” in a singular form in an embodiment of the present disclosure and the attached claims are also intended to include plural forms thereof, unless explicitly noted otherwise in the context.

In some related technologies, in order to improve the impact resistance of the display panel, a size of an aluminum plate structure on the back of the panel is increased for reinforcement. Since a glass substrate is often used as a substrate for the panel, and there is a difference in the thermal performance between a glass substrate and the aluminum plate and a difference in thermal expansion coefficients between the glass substrate and the aluminum plate, resulting in a relatively large internal stress in a product attached to the aluminum plate in low and high temperature environments and leading to the phenomenon of film layer warping.

In order to solve the problems in the related art, an embodiment of the present disclosure provides a display module. Two substrates are provided in the display module to improve structural strength and impact resistance. Additionally, the side traces arranged on the two substrates are lapped via a lap joint, thereby shortening the extending length of the side traces on the sides of the substrates and improving the product yield. The above is the main technical concept of the present disclosure, and the present disclosure may be illustrated below in specific embodiments.

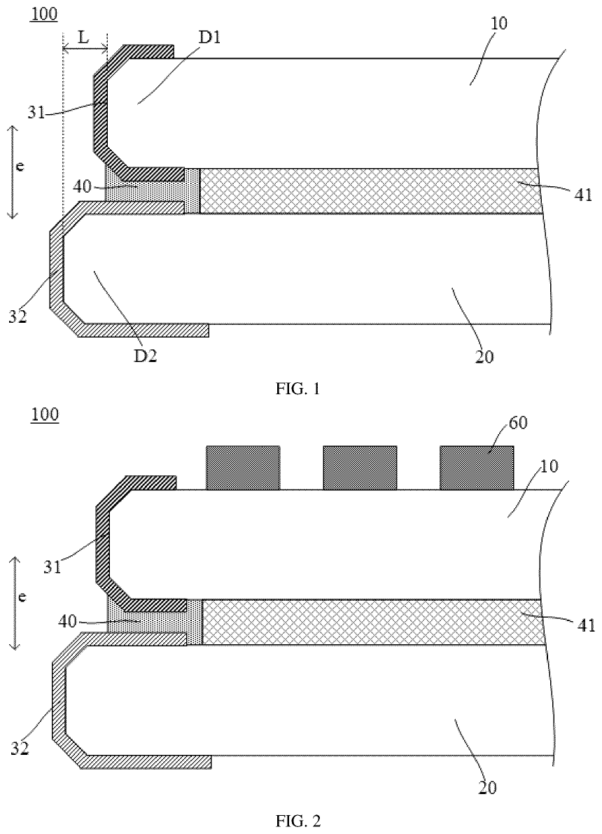

FIG. 1 is a schematic diagram of a display module according to an embodiment of the present disclosure. As shown in FIG. 1, the display module 100 includes a first substrate 10 and a second substrate 20 disposed opposite to each other, a first signal line 31 and a second signal line 32, and a lap joint 40. A light-emitting surface of the display module is located on a side of the first substrate 10 away from the second substrate 20. The light-emitting surface of the display module is a surface displaying an image. The first signal line 31 is provided on a side surface of the first substrate 10, and the second signal line 32 is provided on a side surface of the second substrate 20. The first signal line 31 extends from a side of the first substrate 10 away from the second substrate 20, via the side surface of first substrate 10, to a side of the first substrate 10 close to the second substrate 20. The second signal line 32 extends from a side of the second substrate 20 close to the first substrate 10, via the side surface of second substrate 20, to a side of the second substrate 20 away from the first substrate 10. The lap joint 40 is located between the first substrate 10 and the second substrate 20. The first signal line 31 and the second signal line 32 are electrically connected through the lap joint 40.

The two substrates provided in an embodiment of the present disclosure can increase the overall structural strength of the display module 100, thereby improving the impact resistance. In addition, the first signal lines 31 and the second signal lines 32 respectively provided on the side surfaces of the two substrates are electrically connected to each other through the lap joint 40 located between the two substrates. That is, the side traces do not extend directly and continuously on the two sides of the first substrate 10 and the second substrate 20. Therefore, the extending length of the side traces on a side of the substrate can be shortened, avoiding the impact of excessively long side traces on manufacturing yield. Additionally, an arrangement of the first signal line 31 and the second signal line 32 introduces display signals from a side of the second substrate 20 away from the first substrate 10 without performing a bonding process on a side of the first substrate 10, which can avoid damage to the film layer structure on the side of the first substrate 10 by the process, thus improving the yield. The design of the embodiments of the present disclosure is conducive to increasing product yield and reducing costs.

In addition, as shown in FIG. 1, an adhesive layer 41 is further provided between the first substrate 10 and the second substrate 20. The adhesive layer 41 is entirely laid between the first substrate 10 and the second substrate 20. The adhesive layer 41 can ensure tight bonding between the first substrate 10 and the second substrate 20, thereby improving the overall structural strength, and avoiding displacement between the first substrate 10 and the second substrate 20 caused by collision. The adhesive layer 41 may be glass adhesive or double-sided adhesive.

In some embodiments, FIG. 2 is a schematic diagram of another display module according to an embodiment of the present disclosure, as shown in FIG. 2, the display layer is located on a side of the first substrate 10 away from the second substrate 20. For example, a plurality of light-emitting devices 60 are further provided on a side of the first substrate 10 away from the second substrate 20, and the light-emitting devices 60 may be light-emitting diodes (LEDs), such as Micro LEDs or Mini LEDs. The display module provided by an embodiment of the present disclosure may be applied to a spliced display product. Display signals are introduced from the back of the module by using the first signal line 31 and the second signal line 32, thereby reducing a frame of the display module, minimizing splicing gaps of the spliced product, and thus improving the overall display effect.

In some other embodiments, the display layer is located on a side of the first substrate 10 away from the second substrate 20. The display layer includes an organic light-emitting diode. In some other embodiments, the display layer includes liquid crystal molecules or electrophoretic particles, which will not be illustrated herein again.

In an embodiment of the present disclosure, the lap joint 40 includes at least one of solder, conductive adhesive, and nano-silver. The material of the lap joint 40 is easy to obtain and the process is simple. The conductive adhesive is a conductive adhesive. The conductive adhesive is doped with conductive microspheres, such as anisotropic conductive adhesive. In a solution in which the lap joint 40 includes the conductive adhesive, the conductive adhesive is coated on the side of the first substrate 10 or the side of the second substrate 20, then the first substrate 10 and the second substrate 20 are aligned. Conductive microspheres in the conductive adhesive are pressed and clamped between the two pads respectively corresponding to the first signal line 31 and the second signal line 32 by applying pressure, thereby achieving electrical connection between the first signal line 31 and the second signal line 32. In a solution including the conductive adhesive, when forming the display module, the requirement for the alignment accuracy of the first substrate 10 and the second substrate 20 is low, the alignment yield is high, and a short circuit between adjacent signal lines can be avoided.

In some embodiments, the first substrate 10 is a glass substrate, and the second substrate 20 includes strengthened glass. The second substrate 20 and the first substrate 10 have similar thermal properties, and strengthened glass has higher strength compared with ordinary glass substrate. The addition of the second substrate 20 in the display module not only can improve the overall strength of the module, but also, due to the similar thermal properties and similar thermal expansion coefficients between the second substrate 20 and the first substrate 10, the addition of the second substrate 20 can improve the thermal stability of the entire module, thereby avoiding significant internal stress and warping in the product under low-temperature and high-temperature test environments, and thus improving the performance reliability of the product.

In an embodiment of the present disclosure, the strengthened glass is designed by using a same high-precision edge grinding as the glass substrate, and then the strengthened glass and the glass substrate are bonded together by using a high-precision bonding process.

In some embodiments, at least one of a strengthening depth, a surface stress and a central tensile stress of the second substrate 20 is greater than that of the first substrate 10. The strengthening depth of strengthened glass refers to a depth of the compressive stress layer formed by chemical strengthening or ion exchange. The greater the strengthening depth, the stronger the impact resistance of the strengthened glass. The surface stress refers to that the surface region is compressed, and this stress helps to inhibit the propagation of surface micro cracks and improve the overall strength. The central tensile stress refers to a tensile force borne by a central part of the material and characterizes the tensile strength of the central part. In an embodiment of the present disclosure, the first substrate 10 serves as a base for carrying the circuit layer and the display function layer, and the impact resistance of the overall structure is enhanced by using the second substrate 20 on a back side of the light-emitting surface, thereby improving the performance reliability of the display module.

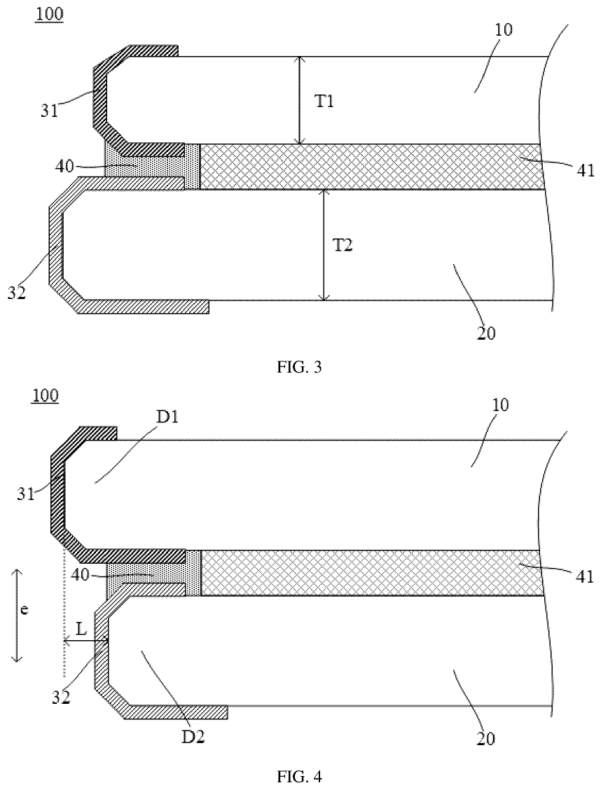

In some embodiments, FIG. 3 is a schematic diagram of another display module according to an embodiment of the present disclosure, as shown in FIG. 3, a thickness of the first substrate 10 is T1, a thickness of the second substrate 20 is T2, and the thickness T2 of the second substrate 20 is greater than the thickness T1 of the first substrate 10. When the first substrate 10 is used as a bearing plate for forming a circuit layer, the thickness of the first substrate 10 may be relatively small. The main function of the second substrate 20 is to enhance the overall structural strength, and the greater the thickness of the second substrate 20, the higher its strength. When T2>T1, the second substrate 20 has a better function of enhancing the overall structural strength.

FIG. 3 only illustrates an optional relationship between the thickness of the first substrate 10 and the thickness of the second substrate 20. In some other embodiments, the thickness of the first substrate 10 may be greater than the thickness of the second substrate 20. The overall structural strength is improved by using the second substrate 20. However, the thickness of the second substrate 20 will not be made too large, which is beneficial to the thinning of the display module.

In some other embodiments, the thickness of the first substrate 10 may be substantially equal to the thickness of the second substrate 20.

In some embodiments, along a thickness direction e of the first substrate 10, at least one end of the second substrate 20 is not aligned with an end of the first substrate 10. It can be understood that the display module includes four ends from a top view, and the corresponding first substrate 10 and second substrate 20 respectively include four ends, and ends of the first substrate 10 and the second substrate 20 are in one-to-one correspondence. Such a misalignment design in this embodiment of the present disclosure has certain advantages. For example, when at least one end of the second substrate 20 is configured to protrude relative to the end of the first substrate 10, the end of the first substrate 10 can be protected by using high strength of the second substrate 20, so that extrusion and collision in the manufacturing process do not affect the first substrate 10. For example, when at least one end of the first substrate 10 is configured to protrude relative to the end of the second substrate 20, the second substrate 20 is visually hidden by the first substrate 10 when viewed from a top view, thereby facilitating narrowing the frame.

In some embodiments, as shown in FIG. 1, the first substrate 10 includes a first end D1. The first signal line 31 is provided on a side surface of the first end D1. The second substrate 20 includes a second end D2. The second signal line 32 is provided on a side surface of the second end D2. Along the thickness direction e of the first substrate 10, the first end D1 is not aligned with the second end D2. FIG. 1 shows that the second end D2 of the second substrate 20 protrudes relative to the first end D1 of the first substrate 10, in other words, the second end D2 extends beyond the first end D1 to form a step. Such an arrangement can protect the first end D1 of the first substrate 10 by using the second end D2 of the second substrate 20, so that extrusion and collision in the forming process do not affect the first end D1. If the second substrate 20 suffers from extrusion and breakage during the process, it can be reworked and repaired by replacing the second substrate 20, thereby avoiding loss of the first substrate 10 and the film layers above it. A circuit layer is formed on the first substrate 10, the circuit layer includes circuit structures such as a pixel circuit and a shift register. The conductive layer in the circuit layer includes at least one semiconductor layer and at least two metal layers, and the conductive layer needs to undergo exposure, development and etching processes to form a pattern, so that the forming cost of the film layer above the first substrate 10 is relatively high. According to this embodiment of the present disclosure, the loss of the first substrate 10 and the film layer above the first substrate 10 can be avoided, thereby avoiding the loss of high-value substrates and thus reducing the forming costs.

FIG. 4 is a schematic diagram of another display module according to an embodiment of the present disclosure. As shown in FIG. 4, the first substrate 10 includes a first end D1. The first signal line 31 is provided on a side surface of the first end D1. The second substrate 20 includes a second end D2. The second signal line 32 is provided on a side surface of the second end D2. Along the thickness direction e of the first substrate 10, the first end D1 is not aligned with the second end D2. The first end D1 protrudes relative to the second end D2, that is, the first end D1 extends beyond the second end D2 to form a step. In this embodiment, when viewed on one side of the display surface, the second end D2 is hidden below the first end D1. The second substrate 20 is used to enhance the overall strength of the display module, and meanwhile, the arrangement of the second substrate 20 does not affect the frame width of the display module.

In some embodiments, as shown in FIG. 1, a depth of the step is L, and L≤100 μm. The depth of the step is an extending length of the end of the second substrate 20 extending beyond the first substrate 10. The second end D2 extends beyond the first end D1 to form a step to protect the first end D1, which can prevent damage to circuit lines on the first end D1. However, a length of the second end D2 extending beyond the first end D1 should not be too long, thereby avoiding waste of space and thus increasing the frame width.

In some other embodiments, as shown in FIG. 4, the first end D1 extends beyond the second end D2 to form a step. A depth of the step is L, and L≤100 μm. In this embodiment, the second end D2 is hidden below the first end D1. When viewed on one side of the first substrate 10, the second end D2 is invisible visually, which can avoid the second end D2 from affecting the frame width of the display module. Meanwhile, the size of L is limited to prevent L from being excessively large, which would result in the second substrate 20 being too small and thus impair the effect of enhancing its impact resistance.

In some embodiments, for example in FIG. 1 or FIG. 4, L≤50 μm.

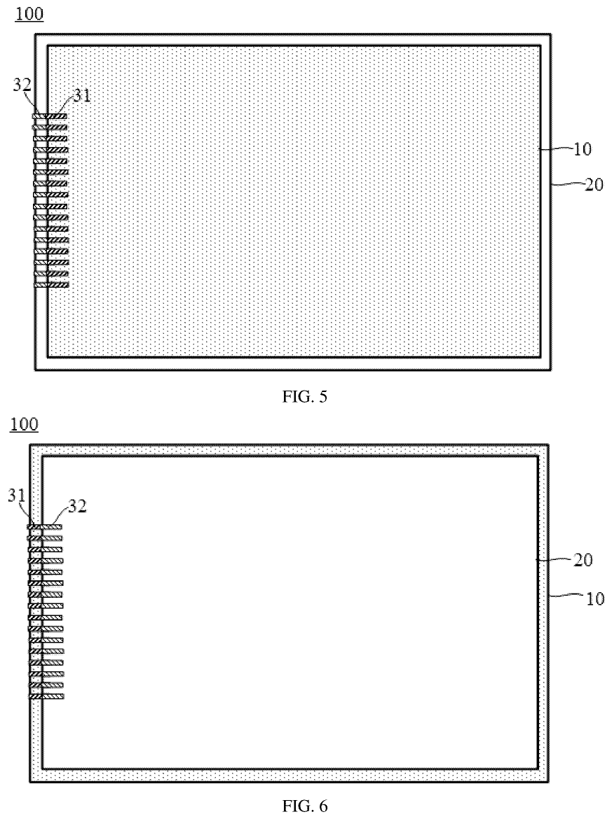

In some embodiments, FIG. 5 is a schematic diagram of another display module according to an embodiment of the present disclosure, FIG. 5 is a top view of the display module 100, in which the first substrate 10 is located above and the second substrate 20 is located below. As can be seen from FIG. 5, all peripheral ends of the second substrate 20 extend beyond the first substrate 10. The peripheral ends of the second substrate 20 in this embodiment can protect the periphery of the first substrate 10 to prevent the first substrate 10 from being affected by the extrusion and collision in the forming process. If the second substrate 20 suffers from extrusion and breakage during the process, it can be reworked and repaired by replacing the second substrate 20, thereby avoiding loss of the first substrate 10 and the film layers above it, and thus reducing the costs.

In some other embodiments, FIG. 6 is a schematic diagram of another display module according to an embodiment of the present disclosure, FIG. 6 is a top view of the display module 100, in which the second substrate 20 is located above and the first substrate 10 is located below. As can be seen from FIG. 6, the peripheral ends of the first substrate 10 extend beyond the second substrate 20. In this embodiment, the second substrate 20 can be used to improve the overall structural strength and impact resistance of the display module 100, and the arrangement of the second substrate 20 does not adversely affect the frame width of the display module.

FIG. 5 and FIG. 6 only illustrate the shape of the display module 100, which may be square or rectangular. The first signal line 31 and the second signal line 32 are located on relatively short end positions of the display module 100, or the first signal line 31 and the second signal line 32 may also be located on relatively long end positions of the display module 100.

In some embodiments, as shown in FIG. 1, the first substrate 10 includes a first end D1. The first signal line 31 is provided on a side surface of the first end D1. The first end D1 includes a first chamfer. The second substrate 20 includes a second end D2. The second signal line 32 is provided on a side surface of the second end D2. The second end D2 includes a second chamfer. According to this embodiment, the first end D1 and the second end D2 are respectively provided with the chamfer. The chamfer at the first end D1 enables the first signal line 31 to be more smoothly provided on the side of the first end D1, thereby avoiding the increase risk of disconnection due to wiring the first signal line 31 on a right-angle end. Similarly, the chamfer at the second end D2 enables the second signal line 32 to be more smoothly provided on the side of the second end D2, thereby avoiding the increase risk of disconnection due to wiring the second signal line 32 on a right-angle end. The two end parts are respectively provided with a chamfer design, which can reduce the risk of disconnection of side traces, thereby improving the product yield.

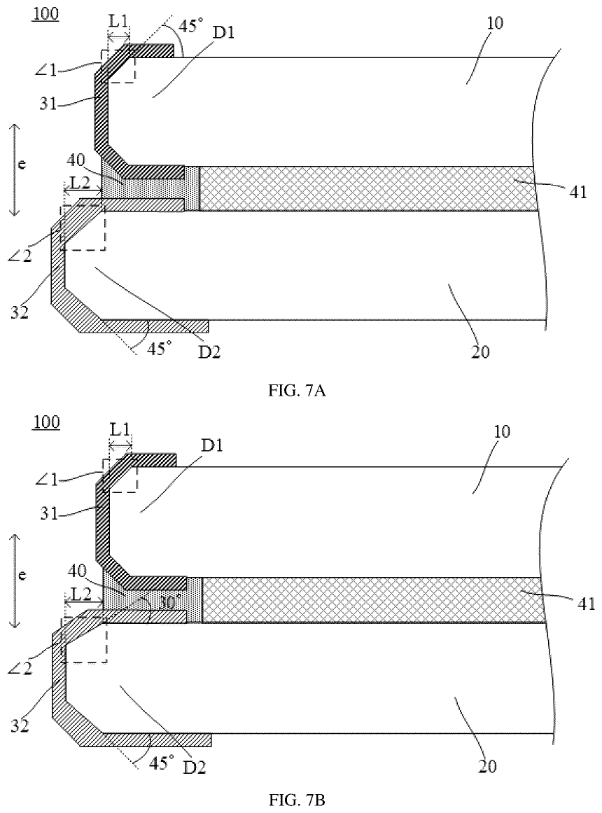

In some embodiments, FIG. 7A is a schematic diagram of another display module provided by an embodiment of the present disclosure. As shown in FIG. 7A, the chamfer at the first end D1 of the first substrate 10 is a first chamfer ∠1, and the chamfer at the second end D2 of the second substrate 20 is a second chamfer ∠2. It can be seen that a length L1 of a right-angle side of the first chamfer ∠1 is less than a length L2 of a right-angle side of the second chamfer ∠2. The first substrate 10 includes two first chamfers ∠1, and the second substrate 20 includes two second chamfers ∠2. Lengths of right-angle sides of the two first chamfers ∠1 of the first substrate 10 may be same or different. Lengths of right-angle sides of the two second chamfers ∠2 of the second substrate 20 may be same or different. In this embodiment of the present disclosure, a length of the right-angle side of any first chamfer ∠1 of the first substrate 10 is less than that of any second chamfer ∠2 of the second substrate 20. The first substrate 10 is provided with circuit lines. Configuring the length L1 of the right-angle side of the first chamfer ∠1 to be relatively short can avoid cutting the lines and causing defects. The second substrate 20 mainly functions to enhance structural strength. The second substrate 20 does not need to be provided with circuit lines, or the wiring space for arranging the circuit lines is relatively large, so that the length L2 of the right-angle side of the second chamfer ∠2 can be configured to be relatively long, which can cut off possible cracks at the edge of the end, thereby avoiding the influence on the edge strength.

In some embodiments, L1 is approximately 30 μm, and L2 ranges from 70 μm to 100 μm.

FIG. 7A illustrates that the two first chamfers ∠1 have a same angle and the two second chamfers ∠2 have a same angle, both of which are approximately 45°. Such an arrangement makes the transition of the first signal line 31 on different surfaces smoother when being provided on the first chamfer ∠1, reducing the risk of line disconnection. Similarly, the risk of line disconnection of the second signal line 32 can also be reduced.

In some embodiments, angles of the two first chamfers ∠1 may be different, angles of the two second chamfers ∠2 may also be different, and the angles of the first chamfers ∠1 and the second chamfers ∠2 may also be different.

In an embodiment, FIG. 7B is a schematic diagram of another display module according to an embodiment of the present disclosure, as shown in FIG. 7B, the first substrate 10 includes two first chamfers ∠1, and the second substrate 20 includes two second chamfers ∠2. Angles of the two first chamfers ∠1 are approximately same to each other, while the angles of the two second chamfers ∠2 are different from each other. In an embodiment, one angle of the second chamfers ∠2 is 45°, and the other angle of the second chamfers is 30°. Such an arrangement enables the retained side surface of the second substrate 20 to have a larger length in direction e under a condition that the thickness of the second substrate 20 and the length L2 of the right-angle side of the second chamfer ∠2 remain unchanged, so that the strength of the end of the second substrate 20 with the chamfer remains high, ensuring its ability to enhance structural strength.

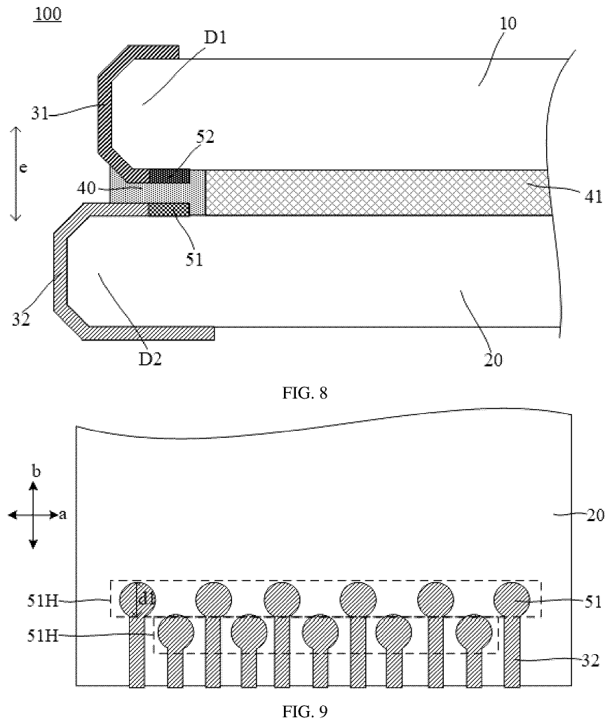

In some embodiments, FIG. 8 is a schematic diagram of another display module according to an embodiment of the present disclosure, as shown in FIG. 8, a side of the second substrate 20 close to the first substrate 10 is provided with a plurality of first pads 51, and one end of the second signal line 32 is electrically connected to the first pad 51. A side of the first substrate 10 close to the second substrate 20 is provided with a plurality of second pads 52, and one end of the first signal line 31 is electrically connected to the second pad 52. The second pads 52 are connected to the first pads 51 in one-to-one correspondence. The lap joint 40 provided between the second pad 52 and the first pad 51 electrically connects the second pad 52 and the first pad 51, thereby implementing electrical connection between the first signal line 31 and the second signal line 32.

In an embodiment, the first pad 51 and the second signal line 32 are formed by a same material, and are formed as an integral structure.

In an embodiment, the second pad 52 and the first signal line 31 are formed by a same material and are formed as an integral structure.

In some embodiments, FIG. 9 is a schematic diagram of another display module according to an embodiment of the present disclosure and illustrates an arrangement of the first pads 51 on the second substrate 20. As shown in FIG. 9, the second substrate 20 is provided with a plurality of first pads 51, and one end of the second signal line 32 is electrically connected to the first pad 51. The second substrate 20 is provided with at least two pad rows 51H. The pad row 51H includes a plurality of first pads 51 arranged in a first direction a. The first direction a is parallel to a plane of the second substrate 20. The first pads 51 of two adjacent pad rows 51H are not aligned in the second direction b. The second direction b intersects with the first direction a. The second direction b is parallel to the plane of the second substrate 20. In this embodiment of the present disclosure, the first pads 51 are arranged in a misaligned manner, which is beneficial to increasing the size of the pads, thereby improving the connection effect between the first substrate 10 and the second substrate 20 and thus ensuring reliable electrical connection performance between the first signal line 31 and the second signal line 32.

The shape of the first pad 51 is not limited in the present disclosure, and FIG. 9 only illustrates that the first pad 51 is circular. The second pad 52 and the first pad 51 are designed in a same shape.

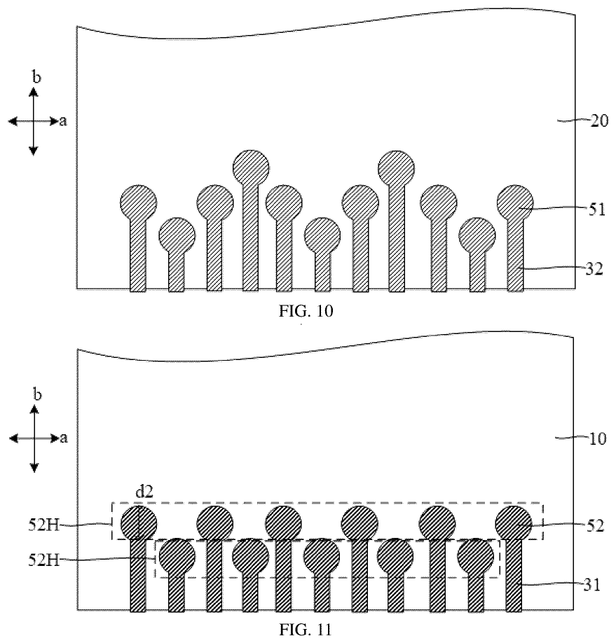

FIG. 9 illustrates that two pad rows 51H are provided on the second substrate 20. In some other embodiments, FIG. 10 is a schematic diagram of another display module according to an embodiment of the present disclosure, as shown in FIG. 10, the first pads 51 on the second substrate 20 are arranged in a distributed manner, and two adjacent first pads 51 are misaligned in both the first direction a and the second direction b. Such an arrangement can increase the size of the first pad 51.

In an embodiment of the present disclosure, the second pads 52 disposed on the side of the first substrate 10 are connected to the first pads 51 on the side of the second substrate 20 in one-to-one correspondence. The second pad 52 on the side of the first substrate 10 needs to adopt a same layout design as the first pad 51. FIG. 11 is a schematic diagram of another display module according to an embodiment of the present disclosure. FIG. 11 illustrates an arrangement of the second pads 52 on the first substrate 10. As shown in FIG. 11, a plurality of second pads 52 are provided on the first substrate 10, and one end of the first signal line 31 is electrically connected to the second pad 52. The first substrate 10 is provided with at least two pad rows 52H. The pad row 52H includes a plurality of second pads 52 arranged in the first direction a. The first direction a is parallel to a plane of the first substrate 10. The second pads 52 of two adjacent pad rows 52H are not aligned in the second direction b. The second direction b intersects with the first direction a. The second direction b is parallel to the plane of the first substrate 10. The second pads 52 on the first substrate 10 shown in FIG. 11 may be matched and correspondingly connected to the first pads 51 on the second substrate 20 shown in FIG. 9.

In some embodiments, an area of the first pad 51 is S1, and an area of the second pad 52 is S2, where S1≥S2. That is, the area of the first pad 51 may be equivalent to the area of the second pad 52, or the area of the first pad 51 is larger than the area of the second pad 52. The size of the pad on the second substrate 20 is set to be relatively large, so that a certain redundant space exists at the first pad 51, which can reduce the requirement for the alignment accuracy of the first substrate 10 and the second substrate 20 and thus improving the yield of the alignment connection between the first pad 51 and the second pad 52.

In some other embodiments, the area of the first pad 51 is S1, and the area of the second pad 52 is S2, where S2≥S1. That is, the area of the first pad 51 may be equivalent to the area of the second pad 52, or the area of the second pad 52 is larger than the area of the first pad 51. The size of the pad on the first substrate 10 is set to be relatively large, so that a certain redundant space exists at the second pad 52, which can reduce the requirement for the alignment accuracy of the first substrate 10 and the second substrate 20 and thus improving the yield of the alignment connection between the first pad 51 and the second pad 52.

In some other embodiments, the first pad 51 includes a first sub-pad and a second sub-pad, and the second pad 52 includes a third sub-pad and a fourth sub-pad. An area of the first sub-pad is greater than an area of the fourth sub-pad, and an area of the third sub-pad is greater than an area of the second sub-pad. That is, an area S1 of part of the first pads 51 is greater than an area S2 of part of the second pads 52, and an area S2 of the remaining part of the second pads 52 is greater than an area S1 of the remaining part of the first pads 51. In this way, such an arrangement can balance the configuration space of the first substrate 10 and the second substrate 20, which not only improves the pad alignment connection yield, but also ensures that adjacent pads are isolated from each other.

As shown in FIG. 9, a length of the first pad 51 in the second direction b is d1. As shown in FIG. 11, a length of the second pad 52 in the second direction b is d2, where d1≥d2, or d2≥d1. Taking the first pad 51 and the second signal line 32 as illustrated in FIG. 9 as an example, it can be seen that a width of the second signal line 32 in the first direction a is smaller than a width of the first pad 51 in the first direction a. The second signal line 32 is a straight line. A boundary where the first pad 51 is in contact with the second signal line 32 and where the width changes in the second direction b is taken as a measurement boundary for the length of the first pad 51 in the second direction b. The second pad 52 is measured in the second direction b in a same manner as the first pad 51.

In some embodiments of the present disclosure, the lengths of the two pads in the second direction b are equivalent, or the length of the first pad 51 in the second direction b is relatively large. When the length of the first pad 51 in the second direction b is relatively large, the area of the first pad 51 can be increased, so that a certain redundant space exists at the first pad 51, thereby improving the yield of the alignment connection between the first pad 51 and the second pad 52.

In some embodiments of the present disclosure, the lengths of the two pads in the second direction b are equivalent, or the length of the second pad 52 in the second direction b is relatively large. When the length of the second pad 52 in the second direction b is relatively large, the area of the second pad 52 can be increased, so that a certain redundant space exists at the second pad 52, thereby improving the yield of the alignment connection between the first pad 51 and the second pad 52.

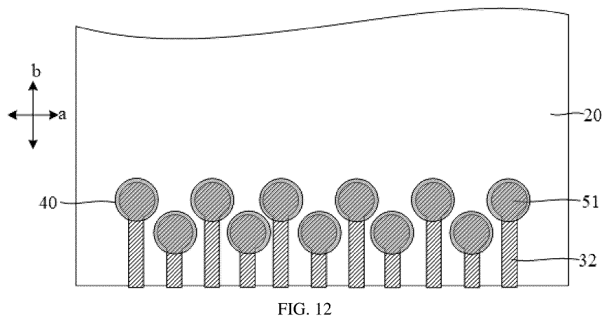

In some embodiments, FIG. 12 is a schematic diagram of another display module according to an embodiment of the present disclosure, and FIG. 12 illustrates that a lap joint 40 is provided on the first pad 51 on the second substrate 20, merely to illustrate an area size relationship between the lap joint 40 and the first pad 51. As shown in FIG. 12, the lap joints 40 are in one-to-one correspondence with the first pads 51, the area of the first pad 51 is S1, and the area of the lap joint 40 is S3, where S3>S1. In this embodiment, the area size of the lap joint 40 is relatively large, which can ensure a large contact area between the lap joint 40 and the first pad 51/the second pad 52, and can improve the yield of the corresponding connection between the first pad 51 and the second pad 52.

In the embodiment of FIG. 12, a plurality of lap joints 40 are provided. The lap joints 40 corresponding to adjacent first pads 51 are independent from each other. The lap joints 40 are solder or nano-silver.

In some other embodiments, the area of the second pad 52 is S2, and the area of the lap joint 40 is S3, where S3>S2, which will not be illustrated herein again. The area size of the lap joint 40 is relatively large, which can ensure a large contact area between the lap joint 40 and the first pad 51/the second pad 52, and can improve the yield of the corresponding connection between the first pad 51 and the second pad 52.

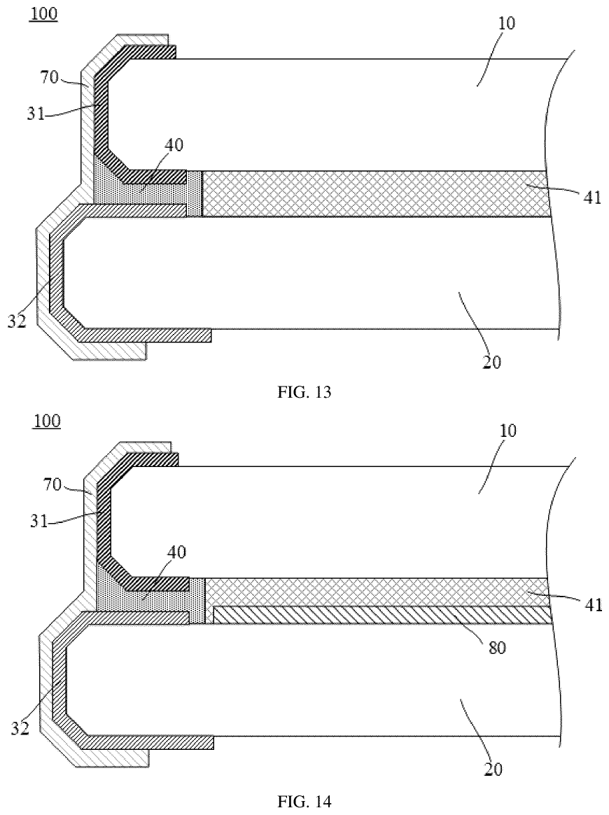

In some embodiments, FIG. 13 is a schematic diagram of another display module according to an embodiment of the present disclosure, as shown in FIG. 13, the display module 100 further includes a protective layer 70 covering the first signal line 31 and the second signal line 32. The protective layer 70 can protect the first signal line 31 and the second signal line 32 from being corroded by water and oxygen, thereby improving the performance reliability of the display module.

In some other embodiments, FIG. 14 is a schematic diagram of another display module according to an embodiment of the present disclosure, as shown in FIG. 14, the display module 100 includes a functional layer 80 located on a side of the second substrate 20 close to the first substrate 10. The functional layer 80 includes a touch layer and/or an infrared detection layer. Firstly, the functional layer 80 is formed on the second substrate 20, and then the second substrate 20 with the fabricated functional layer 80 undergoes alignment and bonding with the first substrate 10. Providing the touch layer on the second substrate 20 can implement a touch function of the display module. Providing the infrared detection layer on the second substrate 20 can monitor the heat distribution of the light-emitting device on the first substrate 10, and then control the light emission of the light-emitting device according to the heat distribution.

A side lead wire may be arranged on the touch layer and/or the infrared detection layer and may be arranged on a same side of the second substrate 20 together with the second signal line 32.

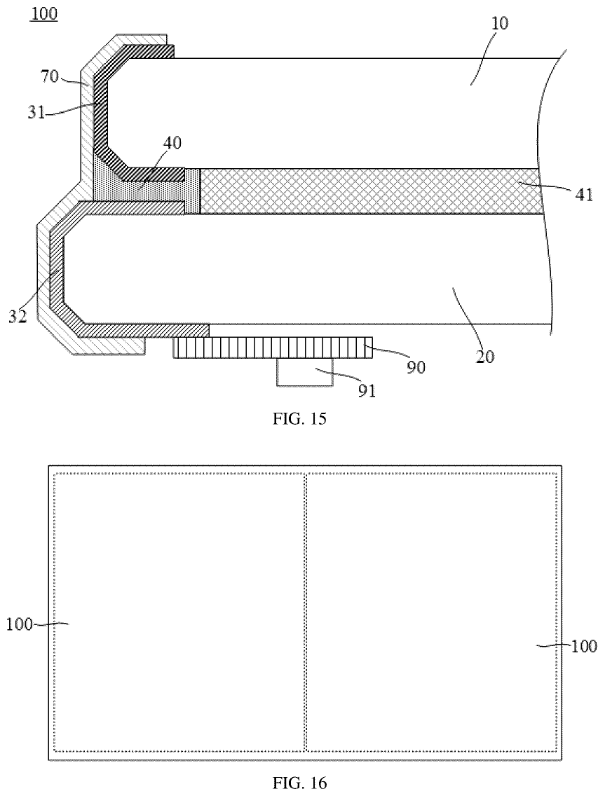

In some embodiments, FIG. 15 is a schematic diagram of another display module according to an embodiment of the present disclosure, as shown in FIG. 15, the display module 100 further includes a flexible circuit board 90 electrically connected to the second signal line 32 on a side of the second substrate 20 away from the first substrate 10. A display driving chip 91 is fixed on the flexible circuit board 90.

Based on the same inventive concept, an embodiment of the present disclosure provides a display device, FIG. 16 is a schematic diagram of a display device provided by an embodiment of the present disclosure, and as shown in FIG. 16, the display device includes the display module 100 provided by any embodiment of the present disclosure. The structure of the display module 100 has been described in the above embodiments and will not be repeated herein again. The display device provided by the embodiments of the present disclosure may be a spliced display device, such as a large conference room screen, and a large exhibition hall screen. The display device provided by the embodiments of the present disclosure may be, for example, an electronic device having a display function, such as a mobile phone, a tablet, a computer, a television, and a smart wearable product.

FIG. 16 illustrates a spliced display device including two display modules 100. In some embodiments of the present disclosure, the display device includes display modules 100 arranged in n rows and m columns, totaling n*m pieces, where both n and m are positive integers and n*m≥2.

The above description merely illustrates some preferred embodiments of the present disclosure and is not intended to limit the present disclosure, and any modification, equivalent substitution, improvement and the like made within a spirit and a principle of the present disclosure shall fall with a scope of the present disclosure.

Finally, it should be noted that, the above-described embodiments are merely for illustrating the present disclosure but not intended to provide any limitation. Although the present disclosure has been described in detail with reference to the above-described embodiments, it should be understood by those skilled in the art that, it is still possible to modify the technical solutions described in the above embodiments or to equivalently replace some or all of the technical features therein, but these modifications or replacements do not cause the essence of corresponding technical solutions to depart from the scope of the present disclosure.

What is claimed is:

1. A display module comprising:
a first substrate and a second substrate disposed opposite to each other, a light-emitting surface of the display module being located at a side of the first substrate away from the second substrate;
a first signal line extending from a side of the first substrate away from the second substrate, via a side surface of the first substrate, to a side of the first substrate close to the second substrate;
a second signal line extending from a side of the second substrate close to the first substrate, via a side surface of the second substrate, to a side of the second substrate away from the first substrate; and
a lap joint between the first substrate and the second substrate,
wherein the first signal line and the second signal line are electrically connected to each other through the lap joint.

2. The display module according to claim 1, wherein
the second substrate comprises strengthened glass.

3. The display module according to claim 1, wherein
at least one of a strengthening depth, a surface stress or a central tensile stress of the second substrate is greater than that of the first substrate.

4. The display module according to claim 1, wherein
a thickness of the second substrate is greater than a thickness of the first substrate.

5. The display module according to claim 1, wherein
at least one end of the second substrate is not aligned with an end of the first substrate along a thickness direction of the first substrate.

6. The display module according to claim 5, wherein
the first substrate comprises a first end, and the first signal line is provided on a side surface of the first end;
the second substrate comprises a second end, and the second signal line is provided on a side surface of the second end; and
the first end and the second end are not aligned with each other along a thickness direction of the first substrate.

7. The display module according to claim 6, wherein
the second end extends beyond the first end to form a step, or the first end extends beyond the second end to form a step.

8. The display module according to claim 7, wherein
a depth of the step is L, and L≤100 μm.

9. The display module according to claim 5, wherein
all peripheral ends of the second substrate extend beyond the first substrate, or
all peripheral ends of the first substrate extend beyond the second substrate.

10. The display module according to claim 1, wherein
the first substrate comprises a first end, the first signal line is provided on a side surface of the first end, and the first end comprises a chamfer; and
the second substrate comprises a second end, the second signal line is provided on a side surface of the second end, and the second end comprise a chamfer.

11. The display module according to claim 10, wherein
the chamfer of the first end is a first chamfer, and the chamfer of the second end is a second chamfer; and
a length of a right-angle side of the first chamfer is smaller than a length of a right-angle side of the second chamfer.

12. The display module according to claim 1, wherein
the lap joint comprises at least one of solder, conductive adhesive, or nano-silver.

13. The display module according to claim 1, wherein
the second substrate is provided with a plurality of first pads on a side close to the first substrate, and one end of the second signal line is electrically connected to one of the plurality of first pads;
the second substrate is provided with at least two pad rows, one of the at least two pad rows comprises multiple first pads arranged in a first direction, and the first direction is parallel to a plane of the second substrate; and
the first pads in two adjacent pad rows are not aligned in a second direction, the second direction intersects with the first direction, and the second direction is parallel to a plane of the second substrate.

14. The display module according to claim 13, wherein
the first substrate is provided with a plurality of second pads on a side close to the second substrate, and one end of the first signal line is electrically connected to one of the plurality pf second pads; and
the plurality of second pads and the plurality of first pads are connected in one-to-one correspondence.

15. The display module according to claim 14, wherein
an area of one of the plurality of first pads is S1, and an area of one of the plurality of second pads is S2, where S1≥S2 or S2≥S1.

16. The display module according to claim 15, wherein
a length of one of the plurality of first pads in the second direction is d1, and a length of one of the plurality of second pads in the second direction is d2, where d1≥d2 or d2≥d1.

17. The display module according to claim 13, wherein
a plurality of lap joints are provided and are in one-to-one correspondence with the plurality of first pads, a plurality of second pads are provided, an area of one of the plurality of first pads is S1, an area of one of the plurality of second pads is S2, and an area of one of the plurality of lap joints is S3, where S3>S1 and/or S3>S2.

18. The display module according to claim 1, further comprising a protective layer covering the first signal line and the second signal line.

19. The display module according to claim 1, further comprising a functional layer located on a side of the second substrate close to the first substrate; wherein
the functional layer comprises at least one of a touch layer or an infrared detection layer.

20. A display device comprising a display module, the display module comprising:
a first substrate and a second substrate disposed opposite to each other, a light-emitting surface of the display module being located at a side of the first substrate away from the second substrate;
a first signal line extending from a side of the first substrate away from the second substrate, via a side surface of the first substrate, to a side of the first substrate close to the second substrate;
a second signal line extending from a side of the second substrate close to the first substrate, via a side surface of the second substrate, to a side of the second substrate away from the first substrate; and
a lap joint between the first substrate and the second substrate,
wherein the first signal line and the second signal line are electrically connected to each other through the lap joint.
